(19) United States
(12) Patent Application Publication
(10) Pub. No.: US 2010/0264478 A1
(43) Pub. Date: Oct. 21, 2010

(54) METHOD TO REDUCE TRENCH CAPACITOR LEAKAGE FOR RANDOM ACCESS MEMORY DEVICE

(75) Inventors: Nace M. Rossi, Singapore (SG); Ranbir Singh, Orlando, FL (US); Xiaojun Yuan, Singapore (SG)

Correspondence Address: HITT GAINES, PC;LSI Corporation, PO BOX 832570, RICHARDSON, TX, 75083, US

(73) Assignee: Agere Systems Inc., Allentown, PA (US)

(21) Appl. No.: 12/680,017

(22) PCT Filed: Oct. 31, 2007
(86) PCT No.: PCT/US07/83176

§ 371 Date: Mar. 25, 2010

(51) Int. Cl. H01L 27/108; H01L 21/02; H01L 21/336; H01L 21/762

(52) U.S. Cl. 257/302; 438/386; 438/270; 257/E21.546; 257/E21.008; 257/E21.41; 257/E27.084

(57) ABSTRACT

A method is provided that includes forming a trench isolation structure in a dynamic random memory region (DRAM) of a substrate and patterning an etch mask over the trench structure to expose a portion of the trench structure. A portion of the exposed trench structure is removed to form a gate trench that includes a first corner formed by the substrate and a second corner formed by the trench structure. The etch mask is removed and the first corner of the gate trench is rounded to form a rounded corner. This is followed by the formation of an oxide layer over a sidewall of the gate trench, the first rounded corner, and the semiconductor substrate adjacent the gate trench. The trench is filled with a gate material.

### CROSS REFERENCE RELATED APPLICATION

This application claims priority of International Application No. PCT/US2007/083176, entitled “METHOD TO REDUCE TRENCH CAPACITOR LEAKAGE FOR RANDOM ACCESS MEMORY DEVICE”, filed on Oct. 31, 2007. The above-listed application is commonly assigned with the present invention and is incorporated herein by reference as if reproduced herein in its entirety.

### TECHNICAL FIELD

The invention is directed, in general, to a method of manufacturing a semiconductor device and, more specifically, to a Random Access Memory (RAM) device that has reduced leakage and method of manufacture therefore.

### BACKGROUND

Memory capacity and the demand for that memory for electronic devices of all types have grown explosively as performance requirements for electronic devices as increased. One way in which memory capacity has been increased is through the use of dynamic random access memory (DRAM). Typical DRAM storage cells are created comprising one single Metal-Oxide-Semiconductor Field-Effect-Transistor (MOSFET) and a single capacitor, this DRAM storage cell is commonly referred to as a 1 T-RAM device. The 1 T-RAM device stores one bit of data on the capacitor as an electrical charge.

Optimization of semiconductor devices continues to be an important goal for the semiconductor industry. The continued miniaturization of semiconductor devices, such as DRAM, presents ongoing challenges to semiconductor manufacturers in maintaining or improving that optimization. As performance requirements have continued to increase, leakage concerns within DRAM areas of semiconductor devices has become a point of focus for the industry.

### SUMMARY

One embodiment of the invention provides a method of manufacturing a semiconductor device. This method includes forming a trench isolation structure in a dynamic random memory region (DRAM) of a semiconductor substrate and patterning an etch mask over the trench isolation structure to expose a portion of the trench isolation structure. A portion of the exposed trench isolation structure is removed to form a gate trench therein, wherein the gate trench includes a first corner formed by the semiconductor substrate and a second corner formed by the trench isolation structure. The etch mask is removed from the DRAM region and at least the first corner of the gate trench is rounded. An oxide layer is formed over a sidewall of the gate trench, the first rounded corner, and the semiconductor substrate adjacent the gate trench, and the trench is filled with a gate material.

Another embodiment includes a method of manufacturing an integrated circuit. This embodiment includes forming first trench isolation structures in a transistor region of a semiconductor substrate, forming second trench isolation structures in a dynamic random memory (DRAM) region of the semiconductor substrate, forming an etch mask over the transistor region and the DRAM region, and patterning the etch mask over the second trench isolation structures to expose a portion of each of the second trench isolation structures with the transistor region remaining protected by the etch mask. A portion of the exposed portions is removed to form a gate trench in each of the second trench isolation structures, wherein each of the gate trenches include a first corner formed by the semiconductor substrate and a second corner formed by the trench isolation structure. This embodiment further includes removing the etch mask from the DRAM region, rounding at least the first corner of each of the gate trenches, forming an oxide layer over a sidewall, the first rounded corner, and the semiconductor substrate adjacent each of the gate trenches, forming a gate oxide over the semiconductor substrate in the transistor region. Additional steps include filling each of the gate trenches with a gate material, the gate material extending over at least the first rounded corner and onto the semiconductor substrate adjacent each of the gate trenches, forming the gate material over the transistor region, patterning the gate material in the DRAM region and the transistor region to form gates, and forming source/drains adjacent the gates.

Yet another embodiment includes an integrated circuit device that includes transistors located in a transistor region of a semiconductor substrate and dynamic random access memory (DRAM) transistors located in a DRAM region of the semiconductor device, wherein each DRAM transistor includes an isolation trench wherein a portion of the isolation trench is a gate trench having a conductive gate material located therein, the gate trench having a first outside rounded corner formed by the semiconductor substrate. This device further includes an oxide layer located over a sidewall of the gate trench, the first outside rounded corner, and the semiconductor substrate adjacent the gate trench, the oxide layer having a thickness that ranges from about 2 nm to about 3 nm and has a thickness uniformity that varies by less than about 0.2 nm. Dielectric layers are located over the transistor regions and the DRAM regions, and interconnects are located over and within the dielectric layers that interconnect the transistors and the DRAM transistors.

### BRIEF DESCRIPTION OF THE DRAWINGS

For a more complete understanding of the present invention, reference is now made to the following descriptions taken in conjunction with the accompanying drawings, in which:

FIG. 1 illustrates a semiconductor device as provided by one embodiment of the invention;

FIGS. 2-7 illustrate one method by which the semiconductor device of FIG. 1 may be fabricated;

FIG. 8 illustrates a view of the device of FIG. 1 incorporated into an integrated circuit.

### DETAILED DESCRIPTION

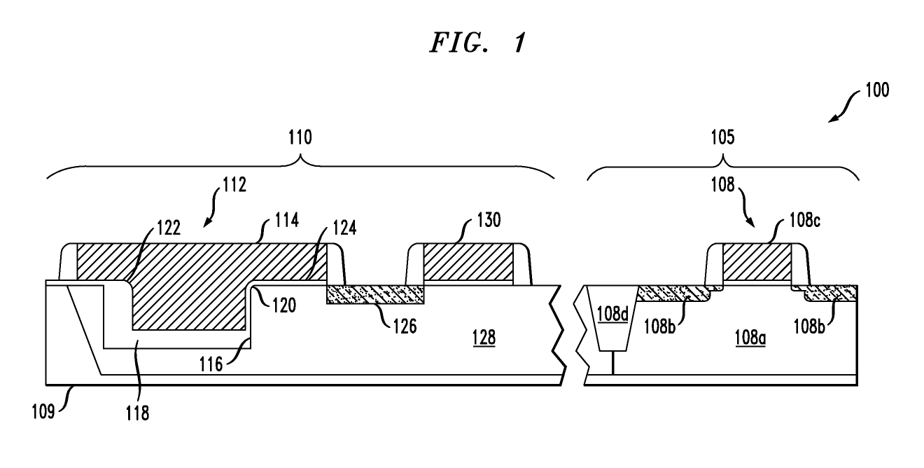

FIG. 1 illustrates an embodiment of a semiconductor device 100 of the invention at an early stage of manufacture. In this embodiment, the semiconductor device 100 includes a transistor region 105 comprising transistors 108 (i.e., PMOS or NMOS transistors that do not form a part of a DRAM storage cell) that are formed over a semiconductor substrate 109, such as an epitaxial layer deposited over a semiconductor wafer or a doped region of the semiconductor wafer. The transistors 108 may be of conventional design, and they may be manufactured with conventional processes and materials known to those skilled in the art. The transistors 108 may be configured as CMOS devices, or they may be configured as all NMOS or PMOS devices. Moreover, it should be understood that though certain dopant schemes are shown and discussed herein, these schemes may be reversed or other dopant schemes may be used. In the illustrated embodiment, the transistor 108 includes a well or tub 108a, source/drains 108b, a gate electrode 108c, and isolation region 108d.

The semiconductor device 100 further includes a DRAM region 110. In this embodiment, the DRAM region 110 includes an embedded capacitor 112 that that has a capacitor electrode 114 comprised of a conductive material, such as a doped polysilicon. The electrode 114 is located within a gate trench 116 formed in an isolation region 118, which may have a thickness of about 40 nm. The gate trench 116, in the illustrated embodiment has first and second rounded corners 120 and 122, although in other embodiments, only the first rounded corner 120 may be present. The first rounded corner 120 is formed by the substrate 109 and the second rounded corner is formed by the isolation region 118. An oxide layer 124 is located over a sidewall of the trench 116 adjacent and on an upper surface of the substrate 109. Due to the presence of the rounded corner 120, the oxide layer 124 has improved uniformity and reduced leakage as compared to conventionally formed devices. Further, in those embodiments that include the second rounder corner 122, less stress is present in the capacitor electrode 114 at the point where the capacitor electrode 114 overlaps the isolation region 118 due to the presence of the second rounded corner 122. The DRAM region 110 further includes a doped source or drain region 126 located within a well 128 and a gate structure 130, all of which may be conventionally formed.

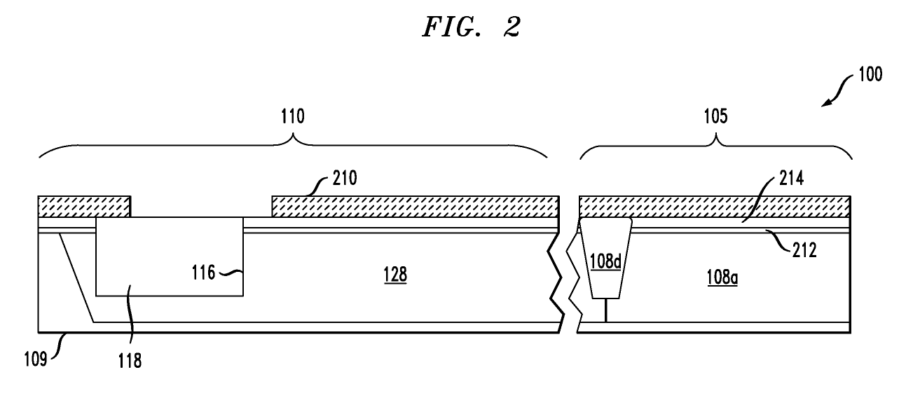

FIG. 2 shows the semiconductor device 100 after the formation of the isolation region 118 and the patterning of a mask 210, such as a photoresist, over a pad oxide layer 212 and nitride layer 214. As seen, the mask 210 is patterned to expose a portion of the isolation region 118 to an etch process and overlap a portion of the isolation region 118.

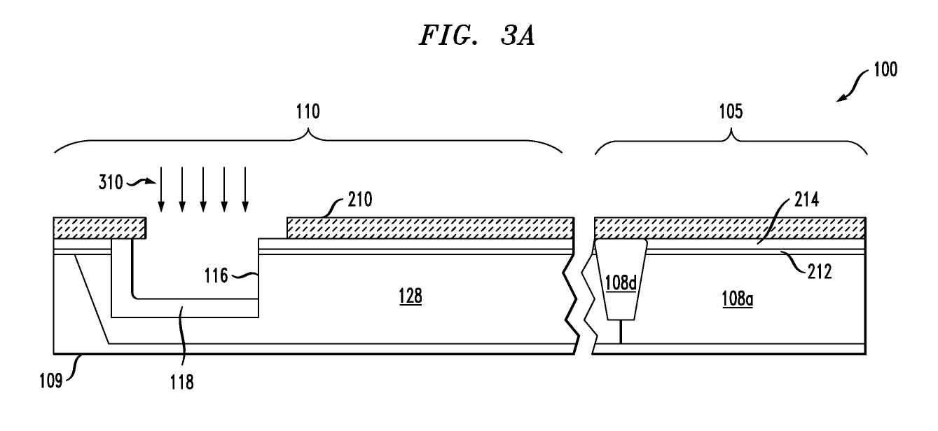

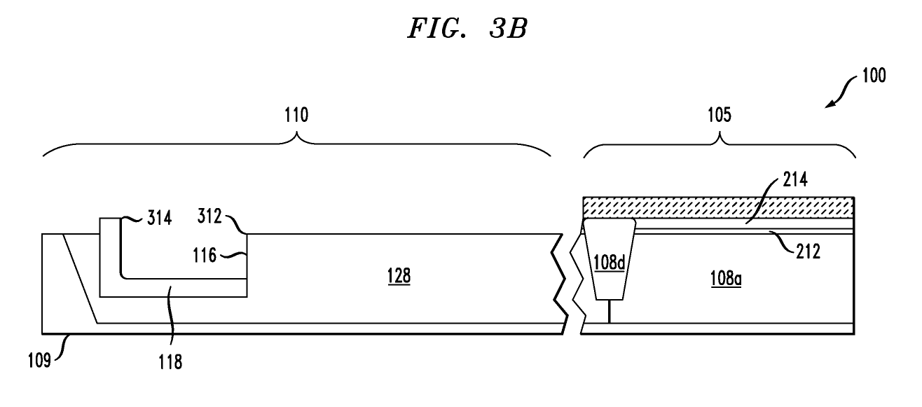

FIG. 3 shows the semiconductor device 100 of FIG. 2 during an etch process 310 that is conducted to remove a portion of the isolation region 118. In one embodiment, the etch process 310 may be a conventional plasma etch process. The etch process 310 is conducted such that a portion of the isolation material remains on the bottom and a sidewall of the isolation region and the mask 210 is undercut, as shown. The thickness of the remaining amount of isolation material may vary and will depend on the amount of gate material required to meet the electrical specifications of the device 100. However, in one embodiment, the thickness of the isolation material remaining at the bottom of the isolation region 118 may be about 100 nm. The etch 310 forms the gate trench 116, which is the trench into which gate material is subsequently deposited. In one embodiment, the gate trench 116 may have a depth of about 300 nm.

Following the etch process 310, the mask 210, the oxide layer 212, and the nitride layer 214 may be conventionally removed from at least the DRAM region 110, as seen in FIG. 3B. The mask 210, the oxide layer 212, and the nitride layer 214 also may be removed from the transistor region 105 at the same time. Alternatively, these layers may re left to protect the transistor region 105 from subsequent fabrication processes. Also seen in FIG. 3B, the etch 310 leaves relatively sharp first and second corners 312, 314 on opposite sides of the trench that have little to no radius of curvature. In such instances, the radius of curvature is less than about 10% of the total depth of the gate trench 116, or stated alternatively, it may be about 56 times the lattice constant, which depends on the type of crystal orientation of the substrate 109. For example, if the gate trench 116 has a depth of about 300 nm, and the silicon has a crystal orientation, the radius of curvature will be less than about 56xa nm, where “a” is equal to 0.54 nm, or about 30 nm. Alternatively, if the silicon has a [110] crystal orientation, the radius of curvature will be less than about 185xa nm, where “a” is equal to 0.19 nm, or about 35 nm. The first corner 312 is formed by the substrate 109, and the second corner 314 is formed by the remaining portion of the isolation region 118.

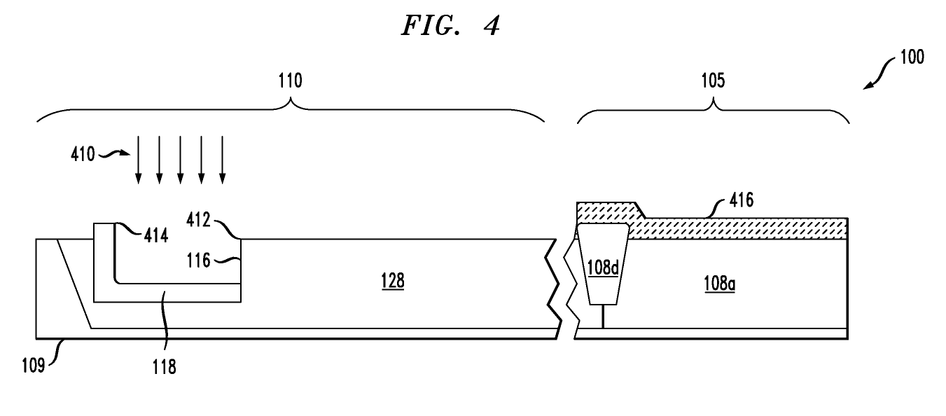

FIG. 4 illustrates the device 100 of FIG. 3B during an etch process 410 that is conducted on the isolation region 118 in the DRAM region 110. The transistor region 105 is protected by a mask 416 so that the isolation regions 108d within the transistor region 105 are unaffected by the etch process 410. The mask 416 may be a newly formed mask or it may be the oxide/nitride layer stack mentioned above. The etch process 410, in one advantageous embodiment, may be a sputter etch process that includes using a gas, such as argon. In this embodiment, the sputter etch may be conducted by flowing the gas at about 100 sccm to about 300 sccm, at a power from about 200 to about 500 watts and at a pressure ranging from about 150 to about 350 milliTorr. The sputter process yielded good corner rounding, which led to a uniform oxide layer in subsequent fabrication processes and reduction of stress in the gate material. In another embodiment, the etch process 410 may be a conventional plasma etch process or a chemical etch process. In the embodiment where both corners 312 and 314 are exposed to the etch, the etch process 410 forms rounded corners 412 and 414 that have a radius of curvature greater than the first and second corners 312 and 314 seen in FIG. 3B. Thus, depending on the gate trench 116 depth and the crystal orientation of the substrate 109, as discussed above, the radius of curvature may be equal to or greater than 10% of the depth of the gate trench 116 or be equal to or greater than 30 nm for [100] silicon or 35 nm for [110] silicon. In an alternative embodiment, a mask may remain over the second corner 314, in such embodiments, only the first corner 312 will be rounded by the etch process 410.

In the embodiment where only the first rounded corner 412 is formed, the invention provides a device with reduced leakage because the rounded corner 412 allows for a more uniform growth of oxide over the rounded corner 412. In an alternative embodiment, further improvements are provided by the invention because the processes of the invention can provide good corner rounding for both the first corner 312 and second corner 314. This dual rounding provides not only a uniform oxide layer over the first corner 312 that reduces leakage, but rounding on the second corner 314 reduces stress on the gate electrode, which can reduce leakage and cracking or voiding of the gate material that covers the second corner 314. Thus, various embodiments of the invention provide improvements over conventional processes used to form buried capacitors in a DRAM device.

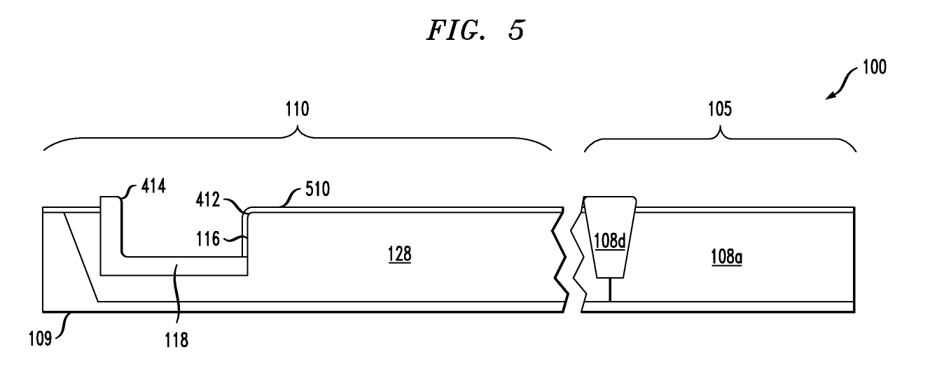

FIG. 5 illustrates the device 100 of FIG. 4 after the formation of an oxide layer 510 over the first rounded corner 412. In a beneficial embodiment, the oxide layer 510 is grown from the surface of the sidewall of the gate trench 116, which is the silicon substrate 109, and on top of the substrate 109. While formation processes may vary, in one embodiment, the oxide layer 510 may be grown by flowing oxygen at a rate ranging from about 7 liters per second to about 10 liters per second and at a temperature ranging from about 1000° C. to about 1100° C. In an advantageous embodiment, the oxide layer 510 covers the rounded corner 412, and in the DRAM region 110, it may have a thickness that ranges from about 2 nm to about 3 nm and has a thickness uniformity that varies by less than about 0.2 nm. This provides a robust gate oxide layer that is less susceptible to leakage, and it is believed that the rounded corner 412 promotes this uniform oxide growth.

The oxide layer thickness in the transistor region 105 may vary, depending on whether the transistors are functioning as a high voltage device or as a core or low voltage device. Thus, the oxide layer in the transistor region 105 may have a different thickness than the oxide layer 510 in the DRAM region 110. In such instances, conventional processes may be used to form the appropriate thickness within the transistor region 105.

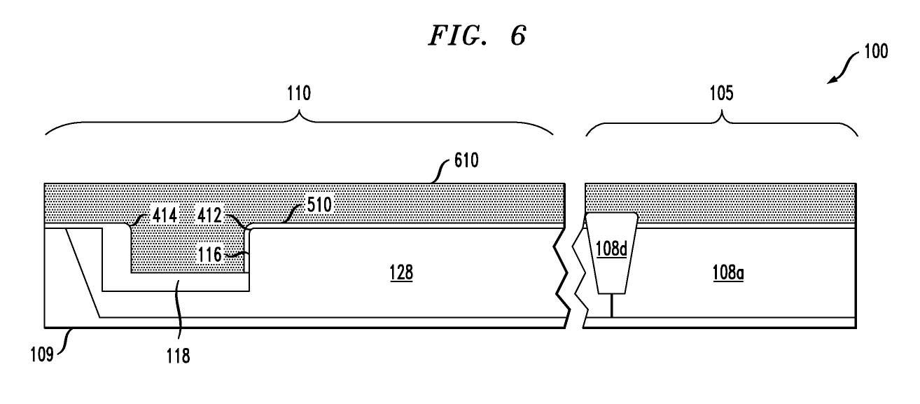

FIG. 6 illustrates the device 100 of FIG. 5 following the deposition of a gate layer 610, such as polysilicon. The gate layer 610 fills the gate trench 116, covers the rounded corners 412 and 414, and extends over the substrate in both the transistor region 105 and the DRAM region 110. Conventional deposition processes may be used to deposit the gate layer 610, and its thickness may vary. The gate layer 610, may be doped with the appropriate dopant and to the desired concentration. Alternatively, the gate layer 610 may not be doped until after it has been patterned to allow for varying dopants and concentration of those dopants to be used.

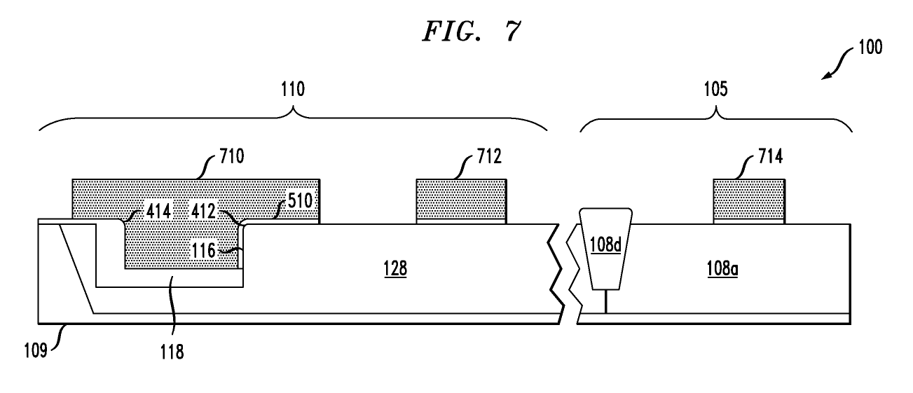

In FIG. 7, following the deposition of the gate layer 610, conventional processes may be used to pattern the gate layer 610 to form a capacitor electrode 710 and associated transistor electrode 712 in the DRAM region 110 and a transistor gate electrode 714 in the transistor region 105. It should be understood that though only one of each of these electrodes is shown, a plurality of these electrodes typically will be present in the device 100. The capacitor electrode 710 and associated transistor electrode 712 may be doped separately from the transistor gate electrode 714 that is located in the transistor region 105, and thus may have a different type of dopant and concentration that transistor electrode 714. As a result of the advantages provided by the invention, the capacitor electrode 710 is improved over devices fabricated using conventional processes because in various embodiments, as described above, both leakage and stress can be reduced on both sides of the capacitor electrode 710 due to the presence of the rounded corners 412 and 414. Following the patterning of the gate layer 610, conventional source/drain implantation processes may be conducted to arrive at the semiconductor device 100 shown in FIG. 1.

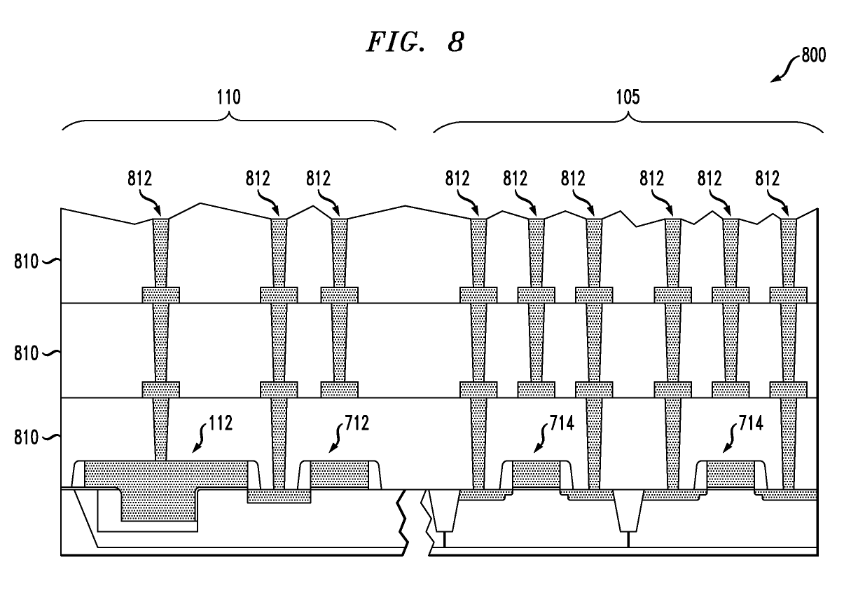

After the structure of FIG. 1 is achieved, conventional fabrication processes can be used to complete an integrated circuit (IC) 800, as seen in FIG. 8, which includes dielectric layers 810 and interconnects 812 formed in and over the dielectric layers 810. The dielectric layers 810 and the interconnects 812 are located over the embedded capacitor 112 and associated transistor electrode 130 in the DRAM region 110 and transistors 108, which may be complementary or non-complementary, in the transistor region 105.

Although the present invention has been described in detail, those skilled in the art should understand that they can make various changes, substitutions and alterations herein without departing from the spirit and scope of the invention in its broadest form.

What is claimed is:

1. A method of manufacturing a semiconductor device, comprising:
forming a trench isolation structure in a dynamic random memory region (DRAM) of a semiconductor substrate;
patterning an etch mask over the trench isolation structure to expose a portion of the trench isolation structure;
removing a portion of the exposed trench isolation structure to form a gate trench therein, wherein the gate trench includes a first corner formed by the semiconductor substrate and a second corner formed by the trench isolation structure;
removing the etch mask from the DRAM region;
rounding at least the first corner of the gate trench;
forming an oxide layer over a sidewall of the gate trench, the first rounded corner, and the semiconductor substrate adjacent the gate trench; and
filling the trench with a gate material.

2. The method recited in claim 1, wherein rounding the first corners further includes rounding the second corner.

3. The method recited in claim 2, wherein rounding the first and second corners includes using a sputter process that includes using a gas flowed at about 100 sccm to about 300 sccm, at a power from about 200 to about 500 watts and at a pressure ranging from about 150 to about 350 milliTorr.

4. The method recited in claim 3, wherein the gas is argon.

5. The method recited in claim 1, wherein forming an oxide layer includes growing an oxide layer from the surface of the sidewall, the first rounded corner and the semiconductor substrate.

6. The method recited in claim 5, wherein the oxide layer has a thickness that ranges from about 2 nm to about 3 nm and has a thickness uniformity that varies by less than about 0.2 nm.

7. The method recited in claim 5, wherein growing the oxide layer includes flowing oxygen at a rate ranging from about 7 liters per second to about 10 liters per second and at a temperature ranging from about 1000° C. to about 1100° C.

8. The method recited in claim 1, wherein a radius of curvature of the first corner is less than a radius of curvature of the first rounded corner.

9. The method recited in claim 1, wherein the semiconductor device is a dynamic random access memory device and wherein filling the gate trench forms a trench capacitor and the method further includes forming a gate electrode adjacent the trench capacitor.

10. A method of manufacturing an integrated circuit, comprising:
forming first trench isolation structures in a transistor region of a semiconductor substrate;
forming second trench isolation structures in a dynamic random memory (DRAM) region of the semiconductor substrate;
forming an etch mask over the transistor region and the DRAM region;
patterning the etch mask over the second trench isolation structures to expose a portion of each of the second trench isolation structures with the transistor region remaining protected by the etch mask;
removing a portion of the exposed portions to form a gate trench in each of the second trench isolation structures, wherein each of the gate trenches include a first corner formed by the semiconductor substrate and a second corner formed by the trench isolation structure;
removing the etch mask from the DRAM region;
rounding at least the first corner of each of the gate trenches;
forming an oxide layer over a sidewall, the first rounded corner, and the semiconductor substrate adjacent each of the gate trenches;
forming a gate oxide over the semiconductor substrate in the transistor region;
filling each of the gate trenches with a gate material, the gate material extending over at least the first rounded corner and onto the semiconductor substrate adjacent each of the gate trenches;
forming the gate material over the transistor region;
patterning the gate material in the DRAM region and the transistor region to form gates; and
forming source/drains adjacent the gates.

11. The method recited in claim 10, wherein rounding the first corners further includes rounding the second corner and filling extending the gate material over the second rounded corner.

12. The method recited in claim 11, wherein rounding the first and second corners includes using a sputter process that includes using a gas flowed at about 100 sccm to about 300 sccm, at a power from about 200 to about 500 watts and at a pressure ranging from about 150 to about 350 milliTorr.

13. The method recited in claim 12, wherein the gas is argon.

14. The method recited in claim 10, wherein forming an oxide layer includes growing an oxide layer from the surface of the sidewall, the first rounded corner, and the semiconductor substrate.

15. The method recited in claim 14, wherein the oxide layer has a thickness that ranges from about 2 nm to about 3 nm and has a thickness uniformity that varies by less than about 0.2 nm.

16. The method recited in claim 10, wherein removing the etch mask from the DRAM region includes removing nitride and oxide layers.

17. An integrated circuit device, comprising:
transistors located in a transistor region of a semiconductor substrate;
dynamic random access memory (DRAM) transistors located in a DRAM region of the semiconductor device, wherein each DRAM transistor includes an isolation trench wherein a portion of the isolation trench is a gate trench having a conductive gate material located therein, the gate trench having a first rounded corner formed by the semiconductor substrate;
an oxide layer located over a sidewall of the gate trench, the first rounded corner, and the semiconductor substrate adjacent the gate trench, the oxide layer having a thickness that ranges from about 2 nm to about 3 nm and has a thickness uniformity that varies by less than about 0.2 nm;
dielectric layers located over the transistor regions and the DRAM regions; and
interconnects located over and within the dielectric layers that interconnect the transistors and the DRAM transistors.

18. The device recited in claim 17, further including and a second rounded corner formed by the trench isolation structure, wherein the gate material overlaps the second rounded corner.

19. The device recited in claim 18, wherein the radius of curvature of the first rounded corner is equal to or greater than about 10% of the depth of the gate trench.

20. The device recited in claim 19, wherein the semiconductor substrate is silicon and has a [100] or [100] crystal orientation and the radius of curvature of about 30 nm for [100] silicon or about 35 nm for [110] silicon.
